(19) United States
(12) Patent Application Publication
(10) Pub. No.: US 2006/0121656 A1
(43) Pub. Date: Jun. 8, 2006

(54) Methods of manufacturing semiconductor devices

(76) Inventor: Kye-Nam Lee, Sungnam-city (KR)

Correspondence Address: HANLEY, FLIGHT & ZIMMERMAN, LLC, 20 N. WACKER DRIVE, SUITE 4220, CHICAGO, IL, 60606, US

(21) Appl. No.: 11/292,249

(22) Filed: Dec. 1, 2005

(30) Foreign Application Priority Data
Dec. 3, 2004 (KR) 10-2004-0101043

(51) Int. Cl. H01L 21/84; H01L 21/00

(52) U.S. Cl. 438/166

(57) ABSTRACT

An example method of manufacturing a semiconductor device includes sequentially forming a gate insulating layer and a polysilicon layer on a semiconductor substrate having a first conductivity type, forming an amorphous silicon layer on a surface of the polysilicon layer by making the surface of the polysilicon layer amorphous, forming a crystallized polysilicon layer by respectively growing grains of the polysilicon layer and the amorphous silicon layer through a heat treatment process for the substrate, forming a gate by patterning the crystallized polysilicon layer, forming an LDD region having a second conductivity type in the substrate at both sides of the gate, forming a spacer at both sidewalls of the gate, and forming a source/drain region having the second conductivity type in the substrate at both sides of the spacer.

### TECHNICAL FIELD

The present disclosure relates to semiconductor devices and, more particularly, to methods of manufacturing semiconductor devices.

### BACKGROUND

Generally, a metal-oxide semiconductor (MOS) transistor is formed of a gate insulating layer on a semiconductor substrate, and a source/drain region in a gate and a semiconductor substrate. According to a type of channel formed in a substrate below the gate, a MOS transistor is classified as a P channel (P-type) transistor or an N channel (N-type) transistor.

In general, the higher the operating speed of a semiconductor device, the higher the gate resistance and contact resistance of a source/drain region are, so as to deteriorate the operation of a MOS transistor. Therefore, a method of forming a silicide layer above a gate and a source/drain region has recently been used in order to prevent deterioration of the operation speed of the MOS transistor

A silicide layer is formed by a self-aligned silicide (SALICIDE) process in which a silicide reaction is selectively performed only on an upper part of a gate and source/drain region without using an additional mask.

Such a conventional method of manufacturing a MOS transistor will now be described with reference to FIG. 1A to FIG. 1D.

As shown in FIG. 1A, a gate insulating layer 11 is formed on a semiconductor substrate 10, and a polysilicon layer 12 of a polycrystalline silicon is deposited on the gate insulating layer 11. Here, the semiconductor substrate 10 is a silicon (Si) substrate.

As shown in FIG. 1B, the polysilicon layer 12 (refer to FIG. 1A) is crystallized by growing grains G thereof by performing a heat treatment process. Subsequently, a photoresist pattern (not shown) is formed on the crystallized polysilicon layer by using photolithography, and then a gate 12a is formed by etching the crystallized polysilicon layer by using the photoresist pattern as a mask.

Thereafter, the photoresist pattern is removed by a well known method, and a pocket region 13 is formed in a substrate 10 at both sides of the gate 12a by ion-implanting impurities of the same conductivity type as the substrate 10 into the substrate 10. For example, P-type impurities are ion-implanted when the substrate 10 is P-type, and N-type impurities are ion-implanted when the substrate 10 is N-type.

Subsequently, a lightly doped drain (LDD) region 14a is formed in the substrate 10 at both sides of the gate 12a by ion-implanting a low concentration of impurities 14 having the opposite conductivity type to that of the substrate 10 into the substrate 10. For example, N-type impurities are ion-implanted when the substrate 10 is P-type, and P-type impurities are ion-implanted when the substrate 10 is N-type.

Because a pocket region 13 is formed more deeply than the LDD region 14a, the concentration of impurities in the substrate 10 around the LDD region 14a is higher than that of a channel region so as to suppress a short channel effect.

As shown in FIG. 1C, an oxide layer, a nitride layer, or a layer of a composition thereof is deposited on the entire surface of the substrate 10 in order to cover the gate 12a, and such a layer is etched back to the degree that the surface of the gate 12a and the substrate 10 is exposed. Consequently, a spacer 15 is formed on both sidewalls of the gate 12a. Subsequently, a source/drain region 16a is formed in the substrate 10 at both sides of the spacer 15 by ion-implanting a high concentration of impurities 16 having the opposite conductivity type to that of the substrate 10 into the substrate 10.

As shown in FIG. 1D, a silicide layer 17, made of a substance such as a titanium silicide (TiSix) or cobalt silicide (CoSix) layer, is formed on only the source/drain region 16a and the upper part of the gate 12a by a silicide process. A silicide process includes depositing a metal silicide layer, such as a titanium silicide or cobalt silicide layer, on the entire surface of a substrate, reacting silicon with a metal by performing heat treatment, and removing a non-reacted portion of the metal layer.

However, impurities implanted in several subsequent ion implantation processes may reach a channel region 100, as shown in FIG. 1C, through the grains G of the gate 12a because, according to a conventional semiconductor device, the grains G grow in substantially a columnar fashion during the heat treatment process for the crystallization of the polysilicon layer 12. Consequently, the channel region 100 can be damaged. Such damage of the channel region 100 may induce more defects in a transistor by decreasing a threshold voltage and increasing drain currents.

In addition, the silicide layer 17 may be formed non-uniformly on the gate 12a during the silicide process due to the large-sized grains G of the polysilicon layer 12, and a gate resistance characteristic may be consequently deteriorated.

### BRIEF DESCRIPTION OF THE DRAWINGS

FIG. 1A to FIG. 1D are cross-sectional views showing sequential stages of a conventional method of manufacturing a semiconductor device.

FIG. 2A to FIG. 2D are cross-sectional views showing sequential stages of a method of manufacturing a semiconductor device according to one disclosed example process.

FIG. 3 shows a gate resistance of a semiconductor device, using a Weibull distribution, fabricated according to one disclosed example process and one conventional semiconductor device.

To clarify multiple layers and regions, the thickness of the layers are enlarged in the drawings. Wherever possible, the same reference numbers will be used throughout the drawing(s) and accompanying written description to refer to the same or like parts. As used in this patent, stating that any part (e.g., a layer, film, area, or plate) is in any way positioned on (e.g., positioned on, located on, disposed on, or formed on, etc.) another part, means that the referenced part is either in contact with the other part, or that the referenced part is above the other part with one or more intermediate part(s) located therebetween. Stating that any part is in contact with another part means that there is no intermediate part between the two parts.

### DETAILED DESCRIPTION

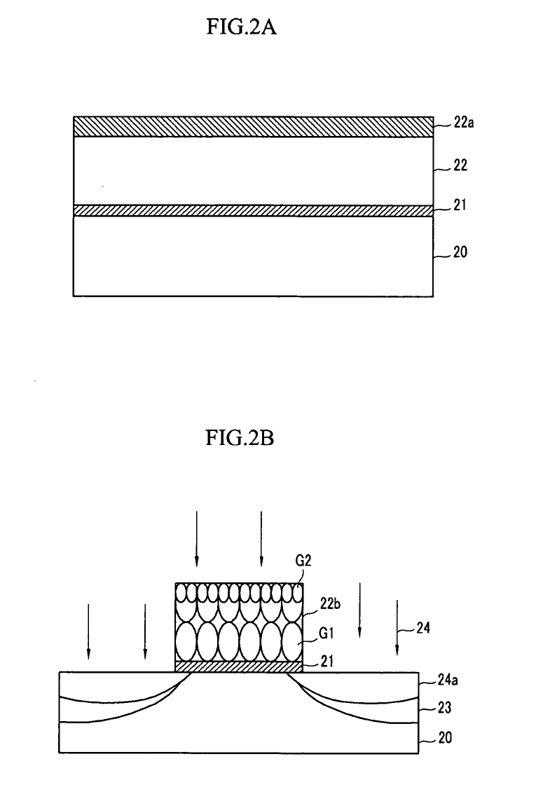

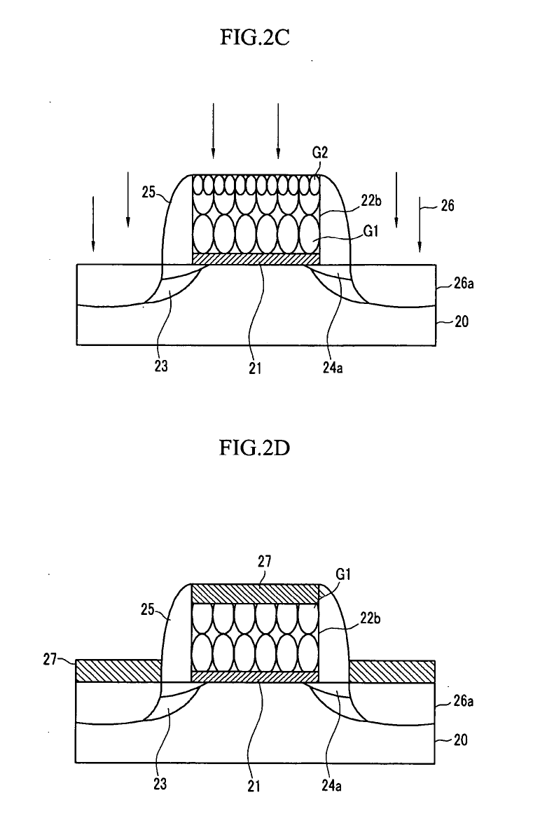

A method of manufacturing a MOS transistor of a semiconductor device according to an example disclosed process will now be described with reference to FIG. 2A to FIG. 2D.

As shown in FIG. 2A, a gate insulating layer 21 is formed on a semiconductor substrate 20, and then a polysilicon layer 22 is deposited on the gate insulating layer 21. In one example, the semiconductor substrate 20 may be a silicon (Si) substrate. Subsequently, an amorphous silicon (Si) layer 22a having grains G2 of a relatively smaller size than grains G1 of the polysilicon layer 22 is formed on the surface of the polysilicon layer 22 by making a surface of the polysilicon layer 22 amorphous through implantation of argon (Ar) into the polysilicon layer 22. In one example, the implantation of argon is performed by blanket ion implantation.

As shown in FIG. 2B, a crystallized polysilicon layer is formed by respectively growing the grains G1 and G2 of the polysilicon layer 22 (refer to FIG. 2A) and the amorphous silicon layer 22a (refer to FIG. 2A) through a heat treatment process. In this case, the grains G2 grow microscopically and uniformly on the surface of the crystallized polysilicon layer because the size of the grains G2 of the amorphous silicon layer 22a is relatively smaller than that of the grains G1 of the polysilicon layer 22. Subsequently, a photoresist pattern (not shown) is formed on the crystallized polysilicon layer by using photolithography, and then the crystallized polysilicon layer is etched by using the photoresist pattern as a mask so as to form a gate 22b.

Thereafter, the photoresist pattern is removed by a well known method, and a pocket region 23 is formed in the substrate 20 at both sides of the gate 22b by ion-implanting impurities of the same conductivity type with the substrate 20 into the substrate 20. For example, P-type impurities are ion-implanted when the substrate 20 is P-type, and N-type impurities are ion-implanted when the substrate 20 is N-type. At this time, implanting impurities into a channel region through the gate 22b can be prevented due to the grains G2 that are grown microscopically and uniformly on the surface of the upper part of the gate 22b.

Subsequently, an LDD region 24a is formed in the substrate 20 at both sides of the gate 22b by ion-implanting low-concentration impurities 24 having an opposite conductivity type to that of the substrate 20 into the substrate 20. For example, N-type impurities are ion-implanted when the substrate 20 is P-type, and P-type impurities are ion-implanted when the substrate 20 is N-type. At this time, implanting impurities into a channel region through the gate 22b can also be prevented due to the grains G2 that are grown microscopically and uniformly on the surface of the upper part of the gate 22b.

Because the pocket region 23 is formed more deeply than the LDD region 24a, a concentration thereof in the substrate 20 around the LDD region 24a is higher than that of the channel region so as to suppress a short channel effect.

As shown in FIG. 2C, an oxide layer, a nitride layer, or a composition layer thereof is sequentially deposited on the entire surface of the substrate 20 in order to cover the gate 22b, and such a layer is etched back to a degree that surfaces of the gate 22b and the substrate 20 are exposed. Consequently, a spacer 25 is formed on both sidewalls of the gate 22b. Subsequently, a source/drain region 26a is formed in the substrate 20 of both sides of the spacer 25 by ion-implanting high concentration impurities 26 having the opposite conductivity type to that of the substrate 20 into the substrate 20. At this time, as described above, implanting impurities into the channel region through the gate 22b can also be prevented due to the grains G2 that are grown microscopically and uniformly on the surface of the upper part of the gate 22b.

As shown in FIG. 2D, a silicide layer 27, such as a titanium silicide (TiSix) or cobalt silicide (CoSix) layer, is formed only on the upper part of the source/drain region 26a and the gate 22b by a silicide process. A silicide process includes depositing a metal silicide layer, such as a titanium silicide or cobalt silicide layer, on the entire surface of a substrate, reacting silicon with a metal by performing heat treatment, and removing a non-reacted portion of a metal layer. At this time, the silicide layer 27 is uniformly formed on the upper part of the gate 22b due to the grains G2 that are grown microscopically and uniformly on the surface of the upper part of the gate 22b.

As described above, according to one example process, grains are grown relatively microscopically and uniformly on a gate surface after crystallizing a polysilicon layer because the surface of a polysilicon layer becomes amorphous before crystallizing a polysilicon layer used for a gate material. Accordingly, damage to a channel region can be prevented by preventing implantation of impurities into a channel region through a gate when impurities are ion-implanted in order to form a pocket region, an LDD region, and a source/drain region. Consequently, defects of a transistor caused by the damage of a channel region are likely to be sharply reduced.

In addition, a gate resistance characteristic is improved because a silicide layer is uniformly formed on the upper part of a gate, with microscopic and uniform grains.

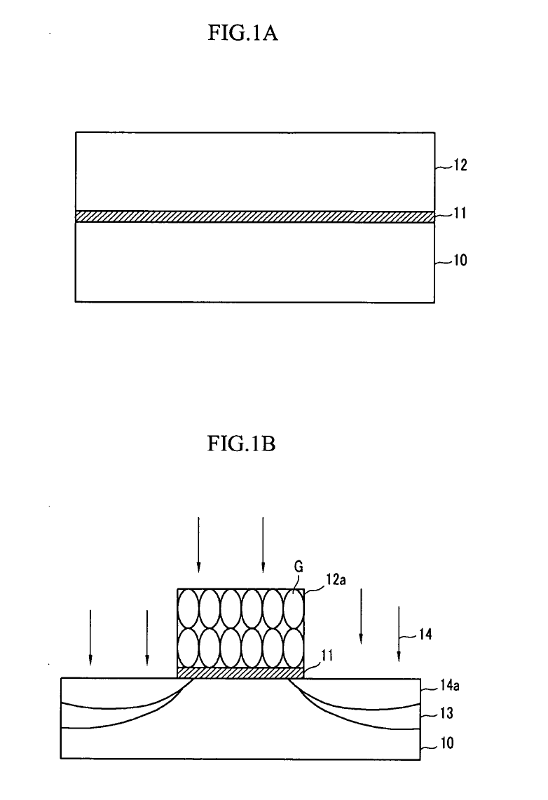

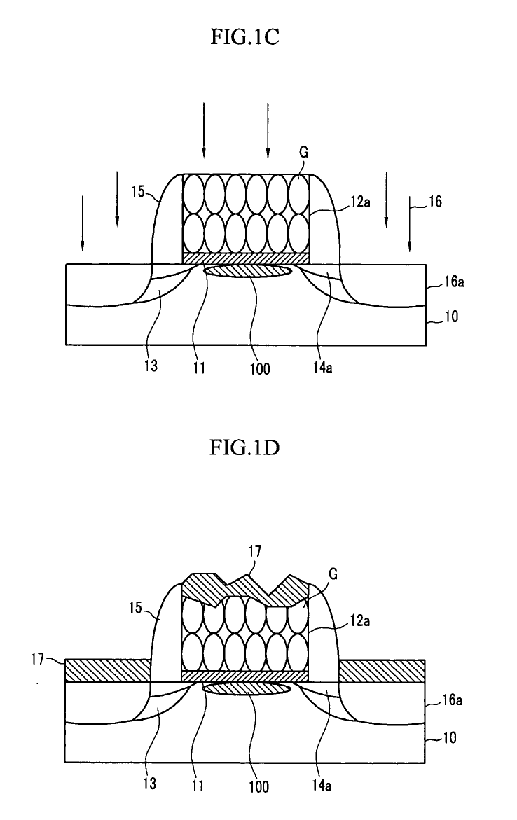

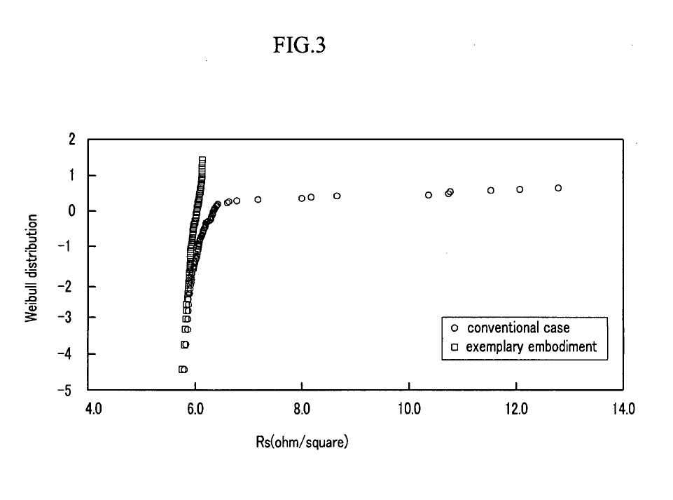

FIG. 3 is a drawing using a Weibull distribution for illustrating a gate resistance (Rs) in both a conventional case (refer FIG. 1D) where a silicide layer is non-uniformly formed and a case fabricated as disclosed herein in which a silicide layer is uniformly formed. The resistance characteristic resulting from the example disclosed process is strongly improved in comparison to the conventional case. Consequently, the electrical characteristics and reliability of a MOS transistor are also improved.

As disclosed herein, a method of manufacturing a semiconductor device has advantages of effectively preventing damage in a channel region and deterioration of a gate resistance characteristic.

One example method of manufacturing a semiconductor device disclosed herein includes sequentially forming a gate insulating layer and a polysilicon layer on a semiconductor substrate having a first conductivity type, forming an amorphous silicon layer on a surface of the polysilicon layer by making the surface of the polysilicon layer amorphous, forming a crystallized polysilicon layer by respectively growing grains of the polysilicon layer and the amorphous silicon layer through a heat treatment process for the substrate, forming a gate by patterning the crystallized polysilicon layer, forming an LDD region having a second conductivity type in the substrate at both sides of the gate, forming a spacer at both sidewalls of the gate, and forming a source/drain region having the second conductivity type in the substrate at both sides of a spacer.

In one example, the crystallized polysilicon layer may be relatively microscopic and uniform grains on the surface in comparison to other regions. In addition, the amorphous silicon layer may be formed by blanket ion implantation of argon into the polysilicon layer.

In a further example, a silicide layer is formed on the upper part of the gate and the source/drain region after forming the source/drain region, and a pocket region having the first conductivity type is formed in the substrate at both sides of the gate between forming of the gate and forming of the LDD region. The pocket region is formed more deeply than the LDD region.

This application claims priority to and the benefit of Korean Patent Application No. 10-2004-0101043 filed in the Korean Intellectual Property Office on Dec. 3, 2004, the entire contents of which are incorporated herein by reference.

Although certain apparatus constructed in accordance with the teachings of the invention have been described herein, the scope of coverage of this patent is not limited thereto. On the contrary, this patent covers every apparatus, method and article of manufacture fairly falling within the scope of the appended claims either literally or under the doctrine of equivalents.

What is claimed is:

1. A method of manufacturing a semiconductor device, comprising:
sequentially forming a gate insulating layer and a polysilicon layer on a semiconductor substrate having a first conductivity type;
forming an amorphous silicon layer on a surface of the polysilicon layer by making a surface of the polysilicon layer amorphous;
forming a crystallized polysilicon layer by respectively growing grains of the polysilicon layer and the amorphous silicon layer through a heat treatment process for the semiconductor substrate;
forming a gate having sidewalls by patterning the crystallized polysilicon layer;
forming an LDD region having a second conductivity type in the semiconductor substrate at both sides of the gate;
forming a spacer at both sidewalls of the gate; and
forming a source/drain region having the second conductivity type in the semiconductor substrate at both sides of the spacer.

2. The method of claim 1, wherein the crystallized polysilicon layer comprises relatively microscopic and uniform grains on its surface in comparison to other regions.

3. The method of claim 2, wherein the amorphous silicon layer is formed by blanket ion implantation of argon into the polysilicon layer.

4. The method of claim 2, wherein a silicide layer is formed on an upper part of the gate and the source/drain region after forming the source/drain region.

5. The method of claim 2, wherein a pocket region having the first conductivity type is formed in the semiconductor substrate at both sides of the gate between forming the gate and forming the LDD region, and the pocket region is formed more deeply than the LDD region.

6. The method of claim 5, wherein the second conductivity type is N-type when the first conductivity type is P-type, and the second conductivity type is P-type when the first conductivity type is N-type.

7. The method of claim 1, wherein the amorphous silicon layer is formed by blanket ion implantation of argon into the polysilicon layer.

8. The method of claim 1, wherein a silicide layer is formed on an upper part of the gate and the source/drain region after forming the source/drain region.

9. The method of claim 1, wherein a pocket region having the first conductivity type is formed in the semiconductor substrate at both sides of the gate between forming the gate and forming the LDD region, and the pocket region is formed more deeply than the LDD region.

10. The method of claim 9, wherein the second conductivity type is N-type when the first conductivity type is P-type, and the second conductivity type is P-type when the first conductivity type is N-type.

11. The method of claim 1, wherein the second conductivity type is N-type when the first conductivity type is P-type, and the second conductivity type is P-type when the first conductivity type is N-type.
